(19) United States
(12) Patent Application Publication
(10) Pub. No.: US 2008/0111586 A1
(43) Pub. Date: May 15, 2008

(54) METHOD FOR DETERMINING A MEMORY TYPE AND RELATED ELECTRONIC DEVICE

(76) Inventors: Kuo-Jen Kuo, Taipei City (TW); Ho-Fu Chen, Kao-Hsiung City (TW)

Correspondence Address: NORTH AMERICA INTELLECTUAL PROPERTY CORPORATION, P.O. BOX 506, MERRIFIELD, VA, 22116, US

(21) Appl. No.: 11/612,476

(22) Filed: Dec. 19, 2006

(30) Foreign Application Priority Data
Nov. 9, 2006 (TW) 095141506

(51) Int. Cl. H03K 5/22

(52) U.S. Cl. 327/77

(57) ABSTRACT

An electronic device for determining a type of a memory includes a comparator and a reset controller. The comparator for generating a discrimination signal according to a reference voltage and a first voltage of the memory, includes a first input end for receiving the first voltage, a second input end for receiving the reference voltage, a logic circuit coupled to the first input end and the second input end, for comparing the first voltage and the reference voltage so as to generate the discrimination signal, and an output end coupled to the logic circuit, for outputting the discrimination signal. The reset controller is used for determining the type of the memory according to the discrimination signal.

### BACKGROUND OF THE INVENTION

1. Field of the Invention

The present invention relates to an electronic device and related method for determining a memory type, and more particularly, to an electronic device and related method for determining a memory type according to a reference voltage.

2. Description of the Prior Art

In an electronic system, memory is an indispensable component for enabling system operations. From cache memory inside a central processing unit (CPU) to video memory on a video card, and even buffers built into hard disk drives, all of these are important memory components. Memory technology has advanced greatly in recent years. Dynamic random access memory (DRAM) has advantages of low price and simple circuit architecture, which drive a large, and increasing, market. DRAM is mainly applied to computer communications and consumer electronic industry products, such as personal computers, digital cameras, mobile phones, etc. There are various types of DRAM, including synchronous dynamic random access memory (SDRAM) and double data rate synchronous dynamic random access memory (DDR-SDRAM). SDRAM, as named, is capable of constantly writing or reading data at a high clock rate (called Burst Transfer) by synchronizing to a rising edge of a clock signal of a system bus. The system bus and processor can achieve pipeline transmission by synchronous operations so that a data processing rate can be increased over previous technologies. DDR-SDRAM performs burst transfer by synchronizing to both the rising and falling edges of the clock signal of the system bus, so as to achieve a double data rate. In other words, the clock rate of DDR-SDRAM is equivalently twice as fast as that of standard SDRAM.

With rapid development of semiconductor technologies, electronic products have reached new levels of miniaturization, such that system-on-a-chip (SOC) technology is increasingly emphasized. An SOC generally includes various types of memory in order to embed operating systems into a microchip. However, different types of memory often adopt different driving specifications, which follow different input/output standards. Such I/O standards include the Joint Electron Device Engineering Council (JEDEC) standard, a low voltage transistor-transistor Logic (LVTTL) standard used in SDRAM, and a stub series terminated logic (SSTL) standard used in DDR-SDRAM. Thus, systems must know which type of memory is being used in advance, so as to provide or switch to suitable input/output voltages for the memory. Thus, it is necessary to determine the type of the memory in advance.

For a system to achieving compatibility with diverse types of memories, US patent publication no. US2004/0133758/A1 discloses a circuit capable of determining memory types, as shown in FIG. 9 of this patent. The circuit includes a preset bias circuit, a latch circuit and an option terminal (OPT). The preset bias circuit provides a bias voltage to the OPT beforehand, and then determines whether to provide an external voltage to the OPT, where the preset bias circuit can output a mode signal with a high or low level. Finally, the system decides to operate at a Single Data Rate (SDR) or a Double Data Rate (DDR) according to the mode signal.

To allow the system to operate normally with two types of memory, the prior art uses a ground pin for providing the external voltage for the OPT so as to determine which mode the system should operate in. However, cost and chip size are always main considerations in implementation of SOCs, so that every pin needs to be arranged properly for the SOC system, which demands a large amount of pins.

### SUMMARY OF THE INVENTION

Therefore, it is an objective of the present invention to provide an electronic device and related method for determining a type of a memory.

The present invention discloses an electronic device for determining a type of a memory comprising a comparator and a reset controller. The comparator for generating a discrimination signal according to a reference voltage and a first voltage of the memory, comprises a first input end for receiving the first voltage, a second input end for receiving the reference voltage, a logic circuit coupled to the first input end and the second input end, for comparing the first voltage and the reference voltage so as to generate the discrimination signal, and an output end coupled to the logic circuit, for outputting the discrimination signal. The reset controller is used for determining the type of the memory according to the discrimination signal.

The present invention further discloses a method of determining a type of a memory. The method comprises receiving a reference voltage; receiving a first voltage outputted from the memory; comparing the first voltage with the reference voltage; generating a discrimination signal according to a result of comparing the first voltage and the reference voltage; and determining a type of the memory according to the discrimination signal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a system for determining a type of a memory according to the present invention.

FIG. 2 is a block diagram of an electronic device of FIG. 1.

FIG. 3 is a flow chart of a method for determining a type of a memory according to FIG. 2.

### DETAILED DESCRIPTION

Double data rate synchronous dynamic random access memory (DDR-SDRAM) includes a basic model (DDR1), and an improved model: double data rate two synchronous dynamic random access memory (DDR2). According to a stub series terminated logic (SSTL) standard, DDR1 must conform to a standard, SSTL-2, which defines an input/output (I/O) voltage of a memory operating at 2.5V and a reference voltage operating at 1.25V, while DDR2 must conform to a standard, SSTL-18, which defines an input/output (I/O) voltage of a memory operating at 1.8V and a reference voltage operating at 0.9V. Additionally, according to a low voltage transistor-transistor logic (LVTTL) standard, an input/output (I/O) voltage of SDRAM has to operate at 3.3V, 2.5V, or 1.8V, and SDRAM does not require a reference voltage.

The present invention utilizes the fact that the diverse memory standards can be identified by the different reference voltages mentioned above. This makes it possible for the system to determine a type of a memory automatically, without using an extra pin, so that the system can adapt to, and be compatible with, more types of memory. In practical implementation, the present invention can eliminate a pin so as to reduce cost, or utilize the pin for other, more practical, functions, so as to increase system efficiency.

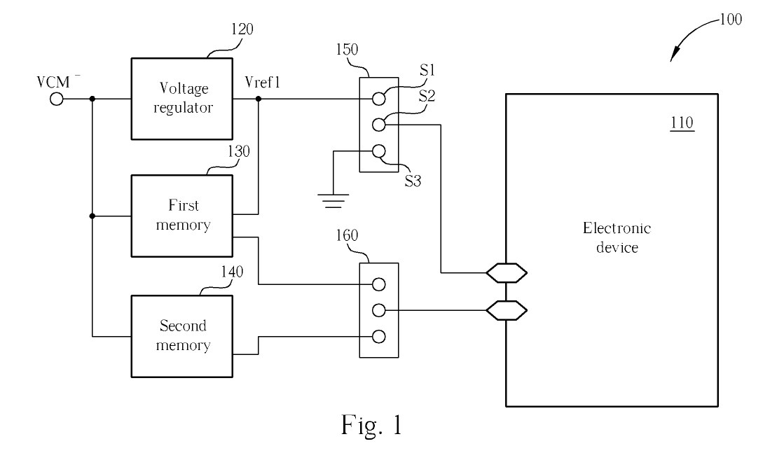

Please refer to FIG. 1. FIG. 1 is a schematic diagram of a system 100 for determining a type of a memory according to the present invention. The system 100 includes an electronic device 110, a voltage regulator 120, a first memory 130, a second memory 140, a first jumper 150 and a second jumper 160. The first memory 130 can be a DDR1, DDR2, or other type of memory, which utilizes a reference voltage for I/O, while the second memory 140 can be an SDRAM or another type of memory, which does not require a reference voltage for I/O. The voltage regulator 120 generates a reference voltage for the first memory 130. The electronic device 110 is the present invention electronic device for determining the type of the memory.

When the system 100 powers on, an operating voltage VCM is provided for the voltage regulator 120, the first memory 130, and the second memory 140. The voltage regulator 120 generates a reference voltage Vref1 conforming to the DDR-SDRAM standard, and inputs the reference voltage Vref1 to the first jumper 150. Herein, if the first memory 130 is DDR1, the reference voltage Vref1 should be 1.25V; if the first memory 130 is DDR2, the reference voltage Vref1 should be 0.9V. The first jumper 150 has three terminals S1, S2 and S3, where the end S1 is adapted to receive the reference voltage Vref1 and the end S3 is grounded. When the system 100 needs to operate with the first memory 130, the end S2 of the first jumper 150 couples to the end S1, whereby the reference voltage Vref1 is transferred to the electronic device 110. On the contrary, when the system 100 needs to operate with the second memory 140, the end S2 of the first jumper 150 couples to the end S3, whereby the electronic device 110 receives a ground voltage 0V, which means that there is no reference voltage, as defined in the LVTTL standard. The electronic device 110 starts to determine the type of the memory after receiving the reference voltage Vref1 or the ground voltage from the first jumper 150. Then, after successfully determining the type of the memory, the electronic device 110 receives data and control signals from the first memory 130 or the second memory 140 via the second jumper 160. Therefore, the system 100 mainly utilizes the voltage regulator 120 to generate the reference voltage Vref1 conforming to the foregoing standards, and transfers the reference voltages corresponding to the different types of memory to the electronic device 110 by the first jumper 150, so that the system 100 can perform determination of the type of the memory. The internal architecture and operations of the present invention electronic device 110 are described in the following.

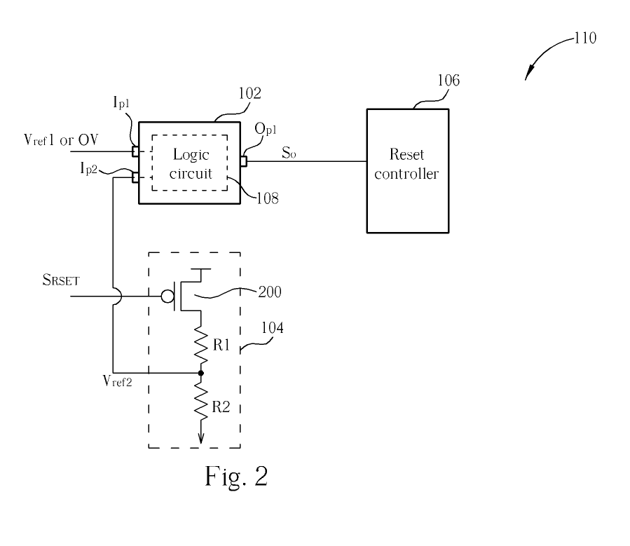

Please refer to FIG. 2. FIG. 2 is a block diagram of the electronic device 110 according to FIG. 1. The electronic device 110 includes a comparator 102, a bias circuit 104, and a reset controller 106. The comparator 102 includes a logic circuit 108, a first input end Ip1, a second input end Ip2, and an output end Op1. The logic circuit 108 is coupled to the first input end Ip1 and the second input end Ip2 and functions to compare a voltage received from the first input end Ip1 with a voltage received from the second input end Ip2 for generating a discrimination signal So. The output end Op1 is used for outputting the discrimination signal So to the reset controller 106. In FIG. 2, the bias circuit 104 includes a P-type metal-oxide semiconductor field effect transistor (MOSFET) 200, which acts as a switch of the bias circuit 104, and resistors R1 and R2 for generating an internal reference voltage after the bias circuit 104 powers on.

After the system 100 powers on, the first jumper 150 switches for transferring the reference voltage Vref1 or the grounded voltage, 0V, to the first input end Ip1. Meanwhile, an external signal enables the electronic device 110 and the bias circuit 104 to start operation. For example, when a signal Sreset pulls down to a low signal level, the MOSFET 200 conducts. The bias circuit 104 simultaneously generates an internal voltage Vref2 by the resistors R1 and R2 and outputs the internal voltage Vref2 to the second input end Ip2, where the embodiment of the present invention sets the internal voltage Vref2 to 0.6V. The logic circuit 108 compares the two voltages inputted to the comparator 102 to determine whether the voltage of the first input end Ip1 is larger than that of the second input end Ip2 or not. If the first input end receives the reference voltage Vref1 and the second input end receives the internal reference voltage Vref2, the reference voltage Vref1 should be 0.9V or 1.25V, whereas the internal reference voltage Vref2 should be 0.6V according to the SSTL standard. Thus, the compared result of the logic circuit 108 is true, and the logic circuit 108 generates the discrimination signal So, which represents a value ‘1’. On the contrary, if the first input end receives the grounded voltage 0V, which is obviously lower than the internal voltage Vref2 0.6V, then the compared result of the logic circuit 108 is false, and the logic circuit 108 generates the discrimination signal So which represents a value ‘0’. Next, after the discrimination signal So is outputted to the reset controller 106, the reset controller 106 determines the type of the memory according to the value of the discrimination signal So. The value ‘1’ of the discrimination signal So indicates DDR memory, whereas the value ‘0’ indicates SDRAM memory. Moreover, a delay circuit (not shown in FIG. 2) can be set up between the comparator 102 and the reset controller 106. The delay circuit includes a plurality of D flip-flops, for retaining the discrimination signal So, so that the reset controller 106 can receive the discrimination signal So after the discrimination signal So stabilizes.

According to the SSTL and LVTTL standards, during an operation period of the DDR-SDRAM, the system 100 generates the reference voltage, 0.9V or 1.25V; during an operation period of the SDRAM, the first jumper 150 is coupled to the end S3, which is coupled to the ground. This shows that the LVTTL standard does not define any standards for reference voltages. Thus, the present invention electronic device 110 compares the reference voltage Vref1 with the internal reference voltage Vref2, and the reset controller 106 determines the type of the memory according to the compared result of the electronic device 110.

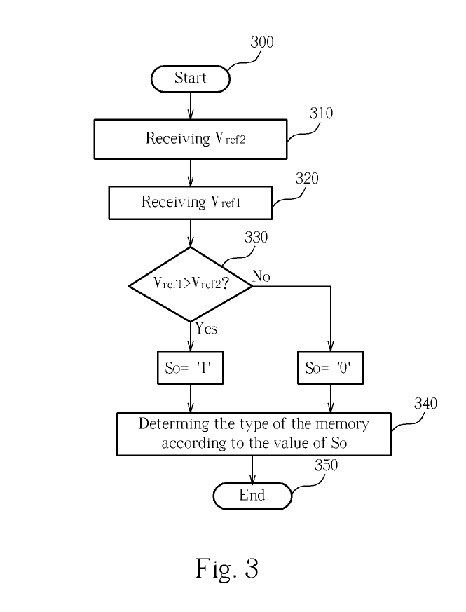

Please refer to FIG. 3. FIG. 3 illustrates a flow chart of a process 30 for determining a type of a memory according to FIG. 2. The process 30 includes the following steps:

300: Start.

310: Receive an internal voltage Vref2.

320: Receive a reference voltage Vref1.

330: Compare the reference voltage Vref1 with the internal voltage Vref2. If the reference voltage Vref1 is greater than the internal voltage Vref2, generate a discrimination signal So with a value ‘1’; else, generate the discrimination signal So with a value ‘0’.

340: Determine the type of the memory according to the value of the discrimination signal So.

350: End.

According to the process 30, in Step 310, the internal reference voltage Vref2 is generated by the bias circuit 104 and is 0.6V. In Step 320, during an operation period of the DDR-SDRAM, the reference voltage Vref1 is 0.9V or 1.25V; during an operation period of the SDRAM, the reference voltage Vref1 is 0V. In Step 340, if the discrimination signal So is ‘1’, the memory is determined to be a DDR; if the discrimination signal So is ‘0’, the memory is determined to be an SDRAM.

Please note that the internal reference voltage Vref2 is adjustable according to different types of memories inside the system or the needs of users, and is not limited to 0.6V. The values of the discrimination signal can be redefined. For example, the value ‘1’ can indicate SDRAM while the value ‘0’ indicates DDR.

In summary, the prior art utilizes one pin coupled to the circuit device for determining the type of the memory. Compared with the prior art, the present invention determines the type of the memory by comparing the reference voltage conforming to the related standards with the internal reference voltage. Therefore, the present invention makes use of the fact that diverse memory standards differ on defining the reference voltage differently, so that systems can automatically determine the type of the memory to increase adaptability and compatibility of systems to different types of memories. Furthermore, the present invention can save one pin in hardware implementation so as to reduce design complexity.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An electronic device for determining a type of a memory comprising:
a comparator for generating a discrimination signal according to a reference voltage and a first voltage of the memory, comprising:
a first input end for receiving the first voltage;
a second input end for receiving the reference voltage;
a logic circuit coupled to the first input end and the second input end, for comparing the first voltage and the reference voltage so as to generate the discrimination signal; and
an output end coupled to the logic circuit, for outputting the discrimination signal; and
a reset controller for determining the type of the memory according to the discrimination signal.

2. The electronic device of claim 1 further comprising a bias circuit for generating the reference voltage.

3. The electronic device of claim 1 further comprising a delay circuit coupled between the output end and the reset controller, for retaining a timing of the discrimination signal.

4. The electronic device of claim 3, wherein the delay circuit comprises a plurality of D flip-flops.

5. The electronic device of claim 1, wherein the memory is a double data rate synchronous dynamic random access memory (DDR-SDRAM).

6. The electronic device of claim 1, wherein the memory is a synchronous dynamic random access memory (SDRAM).

7. The electronic device of claim 1, wherein the reference voltage is 0.6 Volts.

8. A method of determining a type of a memory comprising:
receiving a reference voltage;
receiving a first voltage outputted from the memory;
comparing the first voltage and the reference voltage;
generating a discrimination signal according to a result of comparing the first voltage and the reference voltage; and
determining a type of the memory according to the discrimination signal.

9. The method of claim 8, wherein the reference voltage is generated by a bias circuit.

10. The method of claim 8 further comprising retaining a timing of the discrimination signal.

11. The method of claim 8, wherein the memory is a double data rate synchronous dynamic random access memory (DDR-SDRAM).

12. The method of claim 8, wherein the memory is a synchronous dynamic random access memory (SDRAM).

13. The method of claim 8, wherein the reference voltage is 0.6 Volts.
